(19) United States
(12) Patent Application Publication
(10) Pub. No.: US 2025/0118690 A1
(43) Pub. Date: Apr. 10, 2025

(54) DIELECTRIC STRUCTURE FOR HIGH SPEED INTERCONNECT AND RELIABILITY ENHANCEMENT

(71) Applicant: Taiwan Semiconductor Manufacturing Co., Ltd., Hsinchu (TW)

(72) Inventors: Wen-Yi Lin, New Taipei City (TW); Kan-Ju Yang, Hsinchu (TW); Kai-Cheng Chen, Taoyuan (TW); Chien-Li Kuo, Hsinchu (TW); Chien-Chen Li, Hsinchu (TW)

(21) Appl. No.: 18/482,122

(22) Filed: Oct. 6, 2023

(51) Int. Cl. H01L 23/00; H01L 23/29; H01L 23/31

(52) U.S. Cl. CPC H01L 24/05; H01L 23/293; H01L 23/3192; H01L 24/03; H01L 24/13; H01L 2224/0345; H01L 2224/03452; H01L 2224/03462; H01L 2224/03466; H01L 2224/03903; H01L 2224/03914; H01L 2224/0401; H01L 2224/05018; H01L 2224/05022; H01L 2224/05024; H01L 2224/05027; H01L 2224/0508; H01L 2224/05082; H01L 2224/05084; H01L 2224/05101; H01L 2224/05118; H01L 2224/05124; H01L 2224/05139; H01L 2224/05144; H01L 2224/05147; H01L 2224/05155; H01L 2224/05157; H01L 2224/05166; H01L 2224/05173; H01L 2224/05176; H01L 2224/0518; H01L 2224/05181; H01L 2224/05184; H01L 2224/05186; H01L 2224/05558; H01L 2224/05562; H01L 2224/05572; H01L 2224/05573; H01L 2224/05601; H01L 2224/05618; H01L 2224/05624; H01L 2224/05639; H01L 2224/05644; H01L 2224/05647; H01L 2224/05655; H01L 2224/05657; H01L 2224/05673; H01L 2224/05676; H01L 2224/0568; H01L 2224/05684; H01L 2224/05686; H01L 2224/13021; H01L 2224/13109; H01L 2224/13111; H01L 2224/13116; H01L 2224/1312; H01L 2224/13124; H01L 2224/13139; H01L 2224/13144; H01L 2224/13147; H01L 2224/13155; H01L 2224/13164; H01L 2924/01048; H01L 2924/014; H01L 2924/04941; H01L 2924/04953; H01L 2924/0496

(57) ABSTRACT

A semiconductor package includes: a die having a conductive pad at a first side of the die; and a redistribution structure over the first side of the die and electrically coupled to the die. The redistribution structure includes: a first dielectric layer including a first dielectric material; a first via in the first dielectric layer, where the first via is electrically coupled to the conductive pad of the die; and a first dielectric structure embedded in the first dielectric layer, where the first dielectric structure includes a second dielectric material different from the first dielectric material, where the first dielectric structure laterally surrounds the first via and contacts sidewalls of the first via.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the demand for even smaller electronic devices has grown recently, there has grown a need for smaller and more creative packaging techniques of semiconductor dies.

In an aspect of packaging technologies, redistribution layers (RDLs) may be formed over a die and electrically connected to active devices in the die. Input/output (I/O) connectors such as solder balls on under-bump metallurgy (UBMs) may then be formed to electrically connect to the die through the RDLs. An advantageous feature of this packaging technology is the possibility of forming fan-out packages. Thus, the I/O pads on the die can be redistributed to cover a greater area than the die, and hence the number of I/O pads packed on the surfaces of the packaged dies can be increased.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a semiconductor die, in accordance with an embodiment.

FIGS. 2-11 illustrate cross-sectional views of a semiconductor package at various stages of manufacturing, in accordance with an embodiment.

FIG. 12 illustrates a cross-sectional view of a semiconductor package, in accordance with another embodiment.

FIGS. 13A and 13B illustrate various views of a semiconductor package, in accordance with yet another embodiment.

FIG. 14 illustrates a flow chart of a method of forming a semiconductor package, in accordance with an embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Through the discussion herein, unless otherwise specified, the same or similar reference numeral in different figures refer to the same or similar component formed by a same or similar formation method using the same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a dielectric structure is formed around the sidewalls of a via, and is embedded in a dielectric layer. In some embodiments, the dielectric structure and the dielectric layer are different photosensitive polymers. The Young's modulus and the glass transition temperature of the material of the dielectric structure are higher than those of the dielectric layer. The coefficient of thermal expansion (CTE) of the material of the dielectric structure is substantially the same as that of the dielectric layer. The disclosed via structure reduces the likelihood of cracks being formed between the via and its surrounding structures. A vertically stacked via design, where multiple vias having the disclosed structure are formed to vertically align along the same line, allows for high-density interconnect to be formed, as well as allowing for reduce electrical resistance, power consumption, and RC delay for the device formed.

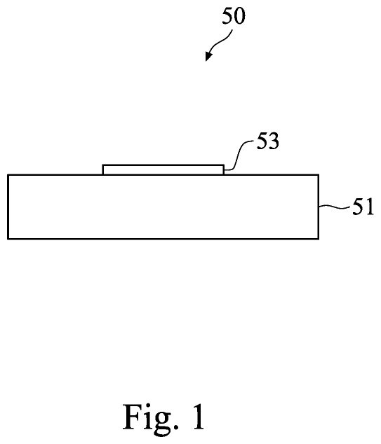

FIG. 1 illustrates a semiconductor die 50 (also referred to as an integrated circuit (IC) die, or a die), in accordance with an embodiment. Note that for simplicity, not all features of the semiconductor die 50 are illustrated. In the illustrated embodiment, the semiconductor die 50 includes a substrate 51, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Devices, such as transistors, diodes, capacitors, resistors, etc., may be formed in and/or on the semiconductor substrate 51 and may be interconnected by interconnect structures formed by, for example, metallization patterns in one or more dielectric layers over the semiconductor substrate to form an integrated circuit.

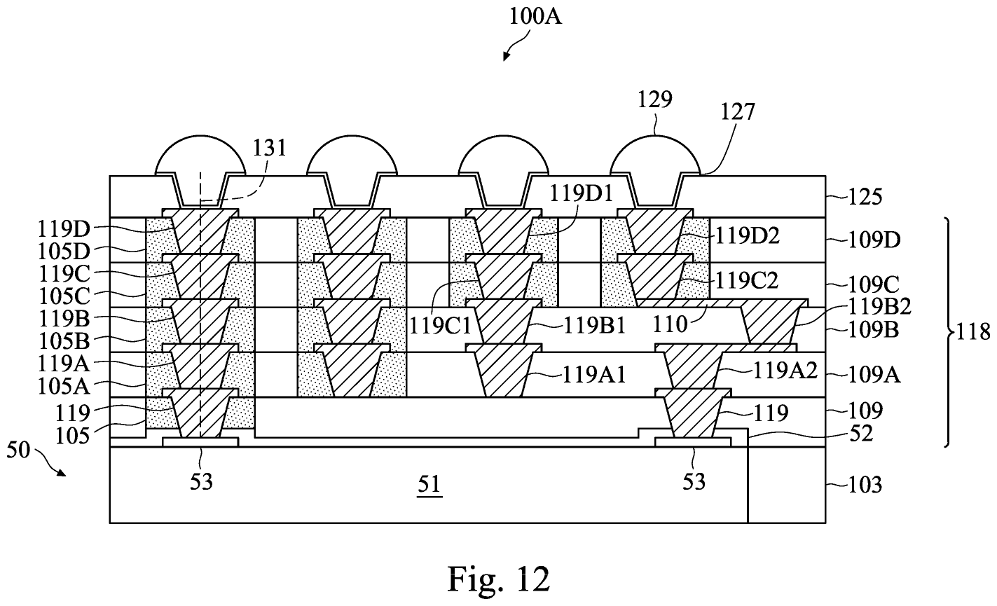

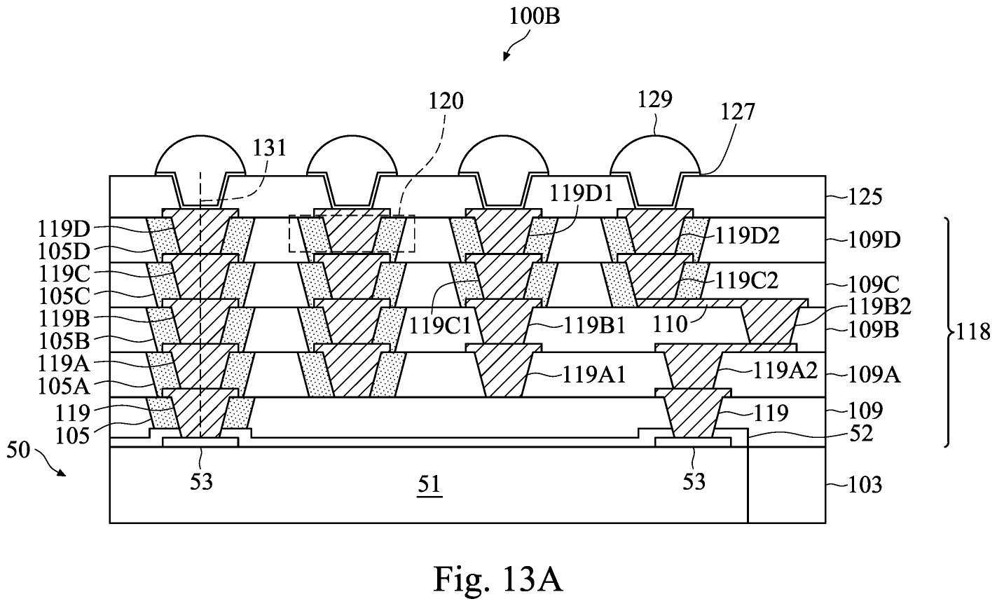

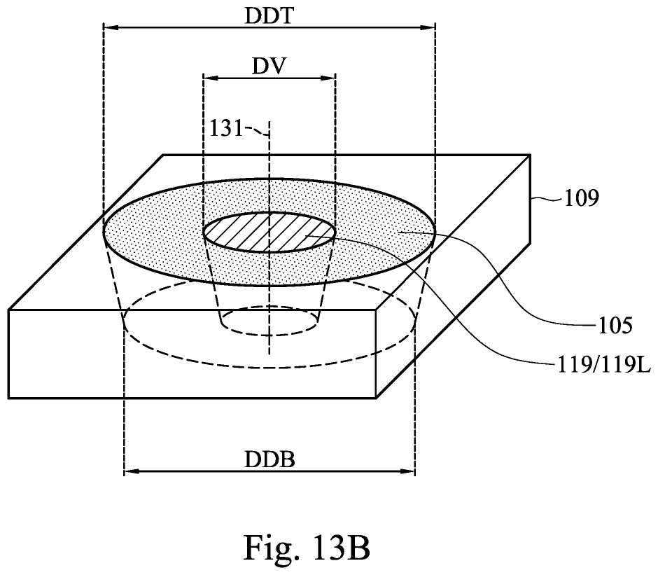

The die 50 further comprises conductive pads 53, such as aluminum pads, to which external connections are made. The conductive pads 53 are on what may be referred to as the active side (or the front side) of the die 50. In the example of FIG. 1, no passivation layer is formed over the conductive pads 53. In other embodiments, passivation layer(s) (see, e.g., 52 in FIGS. 12 and 13A) are formed at the front side the die 50 and on portions (e.g., peripheral portions) of the conductive pads 53.

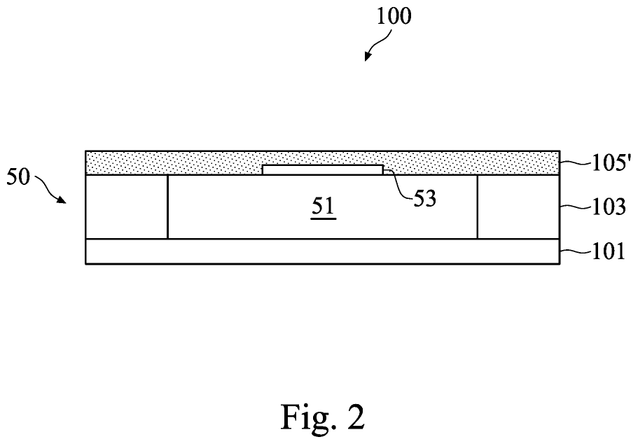

FIGS. 2-11 illustrate cross-sectional views of a semiconductor package 100 at various stages of manufacturing, in accordance with an embodiment.

In FIG. 2, dies 50 are attached to a carrier 101. For simplicity, only one die is shown in FIG. 2 and subsequent figures, with the understanding that any suitable numbers of dies may be attached to the carrier 101. The dies 50 attached to the carrier 101 may be of the same type, or may be of different types. Each of the dies 50 may be a processor die (e.g., a micro-processor, a digital-signal processor (DSP), a central processing unit (CPU), or the like), a logic die, a memory die (e.g., a random-access memory (RAM) die, a flash memory die, a read-only memory (ROM) die, or the like), or the like.

The carrier 101 may be made of a material such as silicon, polymer, polymer composite, metal foil, ceramic, glass, glass epoxy, beryllium oxide, tape, or other suitable material for structural support. An adhesive layer may be deposited or laminated over the carrier 101 for attaching the dies 50, in some embodiments. The adhesive layer may be, e.g., a light-to-heat-conversion (LTHC) coating that can be easily detached from the carrier 101 by shining, e.g., an ultra-violet (UV) light on the carrier 101 in a subsequent carrier de-bonding process.

After the dies 50 are attached to the carrier 101, a molding material 103 is formed over the carrier 101 around the dies 50. The molding material 103 may comprise an epoxy, an organic polymer, a polymer with or without a silica-based or glass filler added, or other materials, as examples. In some embodiments, the molding material 103 comprises a liquid molding compound (LMC) that is a gel type liquid when applied. The molding material 103 may also comprise a liquid or solid when applied. Alternatively, the molding material 103 may comprise other insulating and/or encapsulating materials. The molding material 103 is applied using a wafer level molding process in some embodiments. The molding material 103 may be molded using, for example, compressive molding, transfer molding, or other methods.

Next, the molding material 103 is cured using a curing process, in some embodiments. The curing process may comprise heating the molding material 103 to a predetermined temperature for a predetermined period of time, using an anneal process or other heating process. The curing process may also comprise an ultra-violet (UV) light exposure process, an infrared (IR) energy exposure process, combinations thereof, or a combination thereof with a heating process. Alternatively, the molding material 103 may be cured using other methods. In some embodiments, a curing process is not included.

Next, the molding material 103 is recessed to expose the conductive pads 53. A suitable method, such as chemical mechanical planarization (CMP), an etch back process, combinations thereof, or the like, may be performed to achieve a coplanar upper surface between the molding material 103 and an upper surface of the die 50, and to expose the conductive pads 53.

Next, a dielectric material 105′ is former over the molding material 103 and the dies 50. In an example embodiment, the dielectric material 105′ is a photosensitive polymer deposited by, e.g. a spin coating process. Discussion herein may refer to the dielectric material 105′ as a photosensitive polymer 105′, with the understanding that other suitable material may also be used as the dielectric material 105′. The dielectric material 105′, when formed, covers the conductive pads 53, the upper surfaces of the dies 50, and the upper surface of the molding material 103.

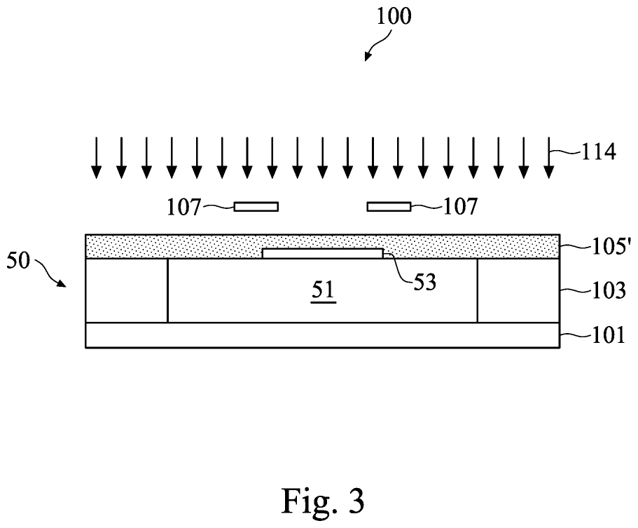

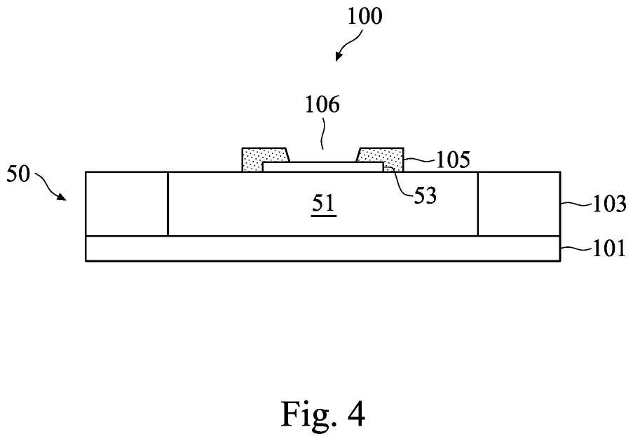

Next, in FIGS. 3 and 4, the dielectric material 105′ is patterned using a suitable patterning process. In an example embodiment, the dielectric material 105′ is a photosensitive polymer, and the patterning process includes an exposure process followed by a developing process.

In the exposure process shown in FIG. 3, a light 114 (e.g., an ultra-violet (UV) light, or the like) is projected through a photomask 107 onto the photosensitive polymer 105′. The photomask 107 (may also be referred to as a reticle) blocks portions of the light 114 and passes through other portions of the light 114. In the illustrated embodiment, the photomask 107 exposes first portions of the photosensitive polymer 105′ (e.g., portions disposed directly over center regions of the conductive pads 53) to the light 114, shields second portions of the photosensitive polymer 105′ (e.g., portions overlapping and contacting peripheral regions of the conductive pads 53) from the light 114, and exposes third portions of the photosensitive polymer 105′ (e.g., portions laterally distal from the conductive pads 53) to the light 114. In some embodiments, the light 114, which projected on the photosensitive polymer 105′, causes changes in the chemical and/or physical properties of the photosensitive polymer 105′, e.g., through cross-linking.

Next, in the developing process shown in FIG. 4, depending on the type of the photosensitive polymer 105′ (e.g., a negative type or a positive type), the exposed portions or the un-exposed portions of the photosensitive polymer 105′ are removed by a developer (e.g., a chemical solution), thereby patterning the photosensitive polymer 105′. In some embodiments, a baking process is performed to further harden the patterned photosensitive polymer 105′. The patterned photosensitive polymer 105′ are also referred to as dielectric structures 105 in the discussion herein.

As illustrated in FIG. 4, the dielectric structure 105 on each conductive pad 53 has an opening 106 that exposes a center region of the upper surface of the conductive pad 53. The dielectric structure 105 covers the peripheral region of the upper surface of the conductive pad 53, and covers the sidewalls of the conductive pad 53.

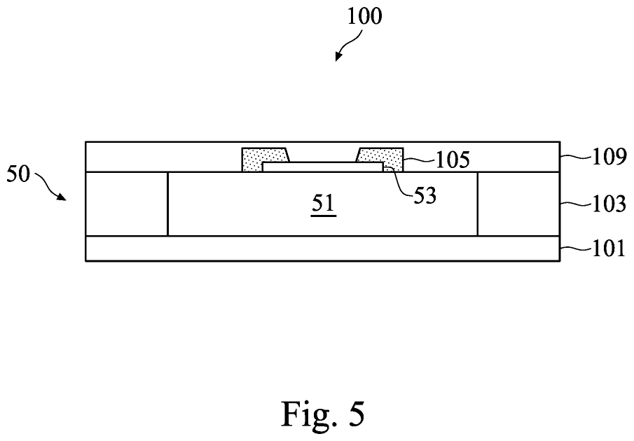

Next, in FIG. 5, a dielectric layer 109 is formed over the dies 50 and the molding material 103. In an example embodiment, the dielectric layer 109 is formed of a photosensitive polymer different from the photosensitive polymer 105′, using a suitable formation method, such as spin coating. The dielectric layer 109 may also be referred to as a photosensitive polymer 109 in the discussion herein, with the understanding that other suitable dielectric material may also be used. The as-deposited photosensitive polymer 109 fills the opening 106 in the dielectric structure 105, and may cover the upper surface of the dielectric structure 105.

In some embodiments, the photosensitive polymer 105′ is harder than the photosensitive polymer 109. For example, the Young's modulus of the photosensitive polymer 105′ is about 3.5 GPa or more at the temperature of 25° C., which is higher (e.g., 20% to 30% higher) than the Young's modulus of the photosensitive polymer 109 at the temperature of 25° C., which may be, e.g., 2.5 GPa or more. In addition, the glass transition temperature of the photosensitive polymer 105′ is higher (e.g., about 20% higher) than the glass transition temperature of the photosensitive polymer 109. For example, the glass transition temperature of the photosensitive polymer 109 is about 200° C. or higher, and the glass transition temperature of the photosensitive polymer 105′ is higher than that of the photosensitive polymer 109 by about 20% or more.

In some embodiments, the coefficient of thermal expansion (CTE) of the photosensitive polymer 105′ is about 30 ppm/° C. or more below its glass transition temperature, and the CTE of the photosensitive polymer 109 is substantially the same (e.g., about 30 ppm/° C. or more) below its glass transition temperature. Here, “substantially” is used to indicate that the CTEs of the photosensitive polymers 105′ and 109 are matching each other within a certain small margin (e.g., within a ±10% margin, or within a ±5% margin). For example, the CTE of the photosensitive polymer 109 may be within a ±10% (or within ±5%) range of the CTE of the photosensitive polymer 105′.

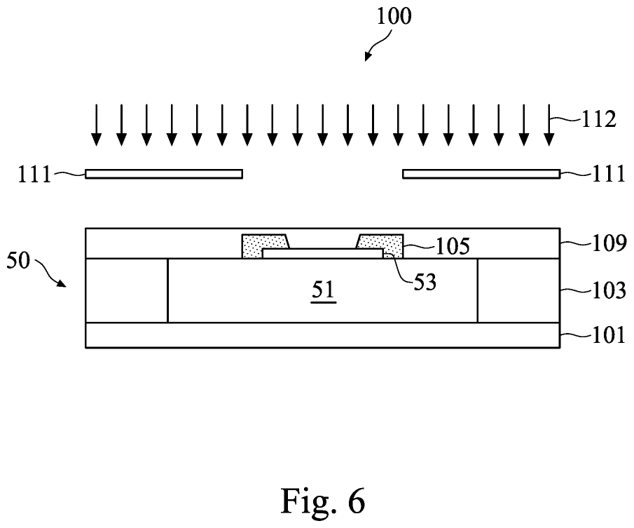

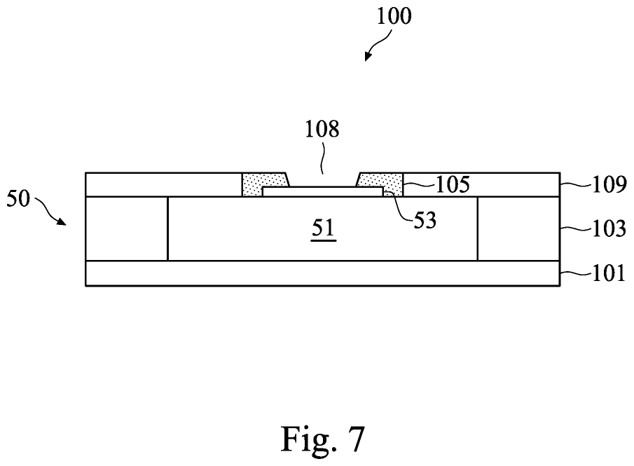

Next, in FIGS. 6 and 7, the dielectric layer 109 (e.g., a photosensitive polymer) is patterned, e.g., using a patterning process comprising an exposure process followed by a developing process. The patterning process for the dielectric layer 109 is similar to that of the photosensitive polymer 105′. FIG. 6 shows the exposure process, where a photomask 111 is used to expose portions of the photosensitive polymer 109 disposed in the opening 106 (see FIG. 4) of the dielectric structure 105, and to shield portions of the photosensitive polymer 109 disposed beyond boundaries (e.g., sidewalls) of the dielectric structure 105. A light 112 is projected through the photomask 111 onto the photosensitive polymer 109 to expose the photosensitive polymer 109.

Next, in FIG. 7, a developing process is performed next to remove the exposed or un-exposed portions of the photosensitive polymer 109. After the developing process, an opening 108 is formed in the dielectric layer 109 at the same location of the opening 106 to expose the center region of the upper surface of the conductive pad 53. In some embodiments, a planarization process, such as CMP, is performed next to remove the dielectric layer 109 from the upper surface of the dielectric structure 105, and to achieve a coplanar upper surface between the dielectric layer 109 and the dielectric structure 105.

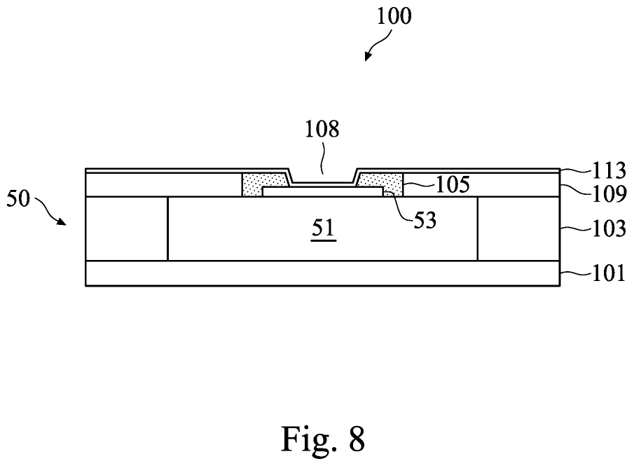

Next, in FIG. 8, a seed layer 113 is formed in the opening 108, along the upper surface of the dielectric layer 109, and along the upper surface of the dielectric structure 105. The seed layer 113 may include copper (Cu), titanium (Ti), tantalum (Ta), titanium nitride (TiN), tantalum nitride (TaN), the like, or a combination thereof, and may be deposited by atomic layer deposition (ALD), sputtering, physical vapor deposition (PVD), or the like. In some embodiments, the seed layer is a metal layer, which may be a single layer or a composite layer comprising a plurality of sub-layers formed of different materials. For example, the seed layer may include a titanium layer and a copper layer over the titanium layer.

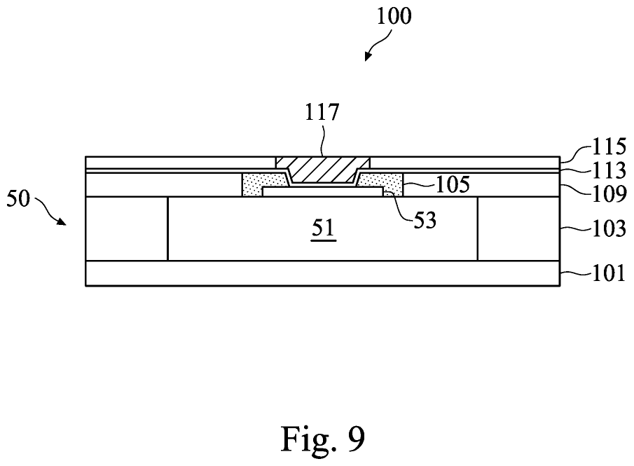

Next, in FIG. 9, a patterned mask layer 115 is formed over the seed layer 113. In an embodiment, the patterned mask layer 115 is a patterned photoresist layer. The patterned photoresist layer has an opening over each opening 108 (see FIG. 8), and the opening in the patterned photoresist layer may be wider than the underlying opening 108. Next, an electrically conductive material 117 is formed on the seed layer 113. The electrically conductive material 117 may comprise a suitable materials such as copper, tungsten, tungsten nitride, rhuthenium, silver, gold, aluminum, rhodium, molybdenum, nickel, cobalt, cadmium, zinc, alloys of these, combinations thereof, or the like. The electrically conductive material 117 may be formed by a suitable formation method, such as electroplating.

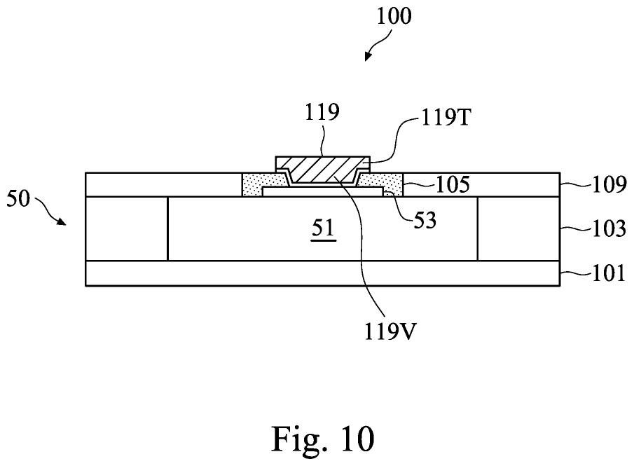

Next, in FIG. 10, the patterned mask layer 115 (e.g., a patterned photoresist layer) is removed by a suitable removal process, such as stripping or ashing. Next, an etching process is performed to remove portions of the seed layer 113 over which no electrically conductive material 117 is formed. After the etching process, the remaining portions of the electrically conductive material 117 and the underlying seed layer 113 form vias 119. Depending on the material used for the seed layer 113 and the electrically conductive material 117, there may or may not be an interface between the seed layer 113 and the electrically conductive material 117 in the via 119.

As illustrated in FIG. 10, the via 119 has an upper portion 119T over the upper surface of the dielectric structure 105, and has a lower portion 119V in the dielectric structure 105. The upper portion 109T may be wider than a widest portion of the lower portion 119V. The lower portion 119V may have slanted sidewalls, due to the effect of the exposure process to form the opening 106.

In the example of FIG. 10, the dielectric structure 105 surrounds the via 119, and contacts and extends along sidewalls of the via 119. The dielectric layer 109 surround the dielectric structure 105, and contacts and extends along sidewalls of the dielectric structure 105. The dielectric layer 109 and the dielectric structure 105 have a same thickness measured along the vertical direction, e.g., between the upper (e.g., uppermost) surface and the lower (e.g., the lowermost) surface of the dielectric layer 109 (or the dielectric structure 105), in some embodiments.

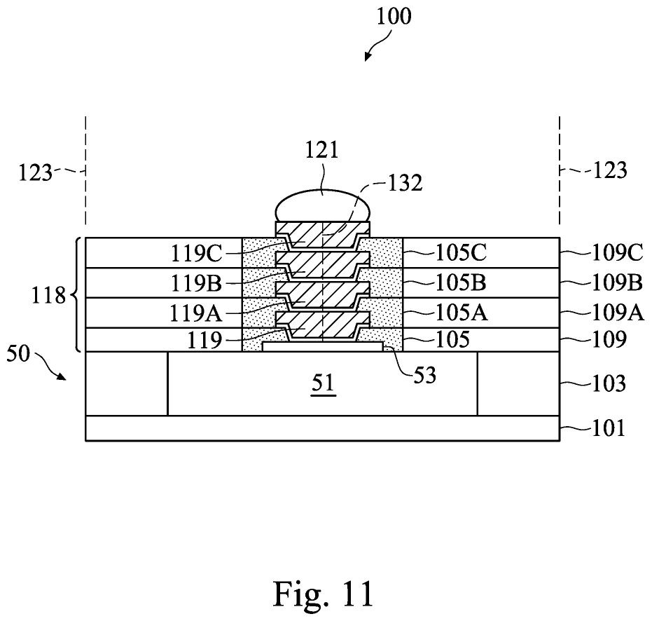

Next, in FIG. 11, the above processing (e.g., FIGS. 2-10) for forming the dielectric structure 105, the dielectric layer 109, and the via 119 are repeated, such that additional dielectric structures 105A-105C, additional dielectric layers 109A-109C, and additional vias 119A-199C are formed over the dielectric layer 109. The number of additional layers of structures formed over the dielectric layer 109 shown in FIG. 11 is illustrative and non-limiting. The dielectric structures 105, 105A-105C, dielectric layers 109, 109A-109C, and vias 119, 119A-199C form redistribution structures (RDS) 118 over the dies 50. In the example of FIG. 11, the dielectric structures 105 and 105A-105C, as well as the vias 119 and 119A-119C, are vertically stacked, such that the center axes 131 (see FIG. 13B) of the vias 119 and 119A-119C are aligned along a same vertical line 132.

Next, connectors 121 are formed on the vias 119C (e.g., the topmost vias). The connectors 121 may be solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like. The connectors 121 may include a conductive material such as solder, copper, aluminum, gold, nickel, silver, palladium, tin, the like, or a combination thereof. In some embodiments, the connectors 121 comprise a eutectic material and may comprise a solder bump or a solder ball, as examples. The solder material may be, for example, lead-based and lead-free solders, such as Pb—Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free connectors such as solder balls may be formed from SnCu compounds as well, without the use of silver (Ag). Alternatively, lead-free solder connectors may include tin and silver, Sn—Ag, without the use of copper. The connectors 121 may form a grid, such as a ball grid array (BGA). In some embodiments, a reflow process may be performed, giving the connectors 121 a shape of a partial sphere in some embodiments. Alternatively, the connectors 121 may comprise other shapes. The connectors 121 may also comprise non-spherical conductive connectors, for example.

In some embodiments, the connectors 121 comprise metal pillars (such as a copper pillar) formed by a sputtering, printing, electro plating, electroless plating, CVD, or the like, with or without a solder material thereon. The metal pillars may be solder free and have substantially vertical sidewalls or tapered sidewalls.

A dicing process may be performed next, e.g., along dicing regions indicated by the lines 123 in FIG. 11, to form individual semiconductor packages 100. Each individual semiconductor package 100 (also referred to as a semiconductor device) may include one or more dies 50, molding material 103 around the one or more dies 50, the RDS 118 over the molding material 103, and connectors 121. The carrier 101 may be removed by a carrier de-bonding process prior to the dicing process, in some embodiments.

The disclosed embodiments achieve various advantage. To appreciate the advantage, consider a reference design where the dielectric structure (e.g., 105) around the via (e.g., 119) is not formed, and the vias (e.g., 119 and 119A-119C) are vertically stacked along a same line. During subsequent thermal cycles, e.g., during reliability test or operation in the field, cracks may form between the vias and the dielectric layer (e.g., 109). This is referred to as a cracking issue. The cracking issue reduces reliability of the device formed, and may cause device failure. One possible way to alleviate the cracking issue is to use a staggered via design, where the vias in different dielectric layers are not vertically aligned along a same line and are not surrounded by the dielectric structures (e.g., 105), but have lateral offsets, with horizontal conductive lines connecting the staggered vias. Compared with the vertically stacked via design disclosed herein, where vias are vertically aligned along a same line and surrounded by respective dielectric structures, the staggered via design has higher electrical resistance, higher power consumption, and larger resistive-capacitive delay (RC delay). In addition, the staggered via design also requires more space for routing, thus limiting the integration density.

In the disclosed embodiments, each of the vias (e.g., 119) is surrounded by a respective dielectric structure (e.g., 105), which dielectric structure is embedded in a respective dielectric layer (e.g., 109). The dielectric structure is formed of a material having a higher Young's modulus and a higher glass transition temperature than that of the respective dielectric layer. The CTE of the material of the dielectric structure is substantially the same as that of the respective dielectric layer. These features, together with other features of the disclosed embodiments, greatly reduces the likelihood of cracks being formed, thereby improving device reliability and production yield. In addition, the vertically stacked via design reduces electrical resistance, power consumption, and the RC delay of the device formed, thus enhancing the performance of the device formed. Furthermore, the vertically stacked via design has a small footprint, thus allowing a higher integration density. Note that the advantage of alleviating the cracking issue is achieved even for a single-layered via structure, which includes a via surrounded by a dielectric structure, which dielectric structure is embedded in a dielectric layer.

FIG. 12 illustrates a cross-sectional view of a semiconductor package 100A, in accordance with another embodiment. The semiconductor package 100A is similar to the semiconductor package 100, and may be formed using the same or similar formation method, as skilled artisans readily appreciate.

In FIG. 12, the die 50 of the semiconductor package 100A has a passivation layer 52 (e.g., a polymer layer such as polyimide) at the front side of the die 50 and partially covering the conductive pads 53. Five dielectric layers, labeled as 109, 109A, 109B, 109C, and 109D, are formed over the die 50, and each of the dielectric layers have embedded dielectric structures (labeled as 105, or 105 with an alphabet such as 105A) formed therein, and each of the dielectric structure surrounds a respective via (which are labeled as 119, or 119 followed by an alphabet or followed by an alphabet and a numeral, such as 105A or 105A1). For ease of discussion, the dielectric layers (or a subset thereof) whose reference numerals include 109 may be collectively referred to as dielectric layers 109, the dielectric structures (or a subset thereof) whose reference numerals include 105 may be collectively referred to as dielectric structures 105, and the vias (or a subset thereof) whose reference numbers include 119 may be collectively referred to as vias 119. The number of dielectric layers 109, and the number and location of the dielectric structures 105 and the vias 119 illustrated in FIG. 12 are illustrative and non-limiting.

The semiconductor package 100A further includes a passivation layer 125 over the top (e.g., topmost) dielectric layer 109D. The passivation layer 125 may be made of one or more suitable dielectric materials such as polybenzoxazole (PBO), although any suitable material, such as polyimide or a polyimide derivative, may alternatively be utilized. Under bump metallurgy (UBM) structure 127 are formed over the passivation layer 125 and is electrically coupled to a respective conducive feature (e.g., a respective via 119). Connectors 129 are formed on the UBM structures 127. The connectors 129 may be the same as or similar to the connectors 121 in FIG. 11, thus details are not repeated.

In an embodiment, the UBM structures 127 comprise three layers of conductive materials, such as a layer of titanium, a layer of copper, and a layer of nickel. However, there are many suitable arrangements of materials and layers, such as an arrangement of chrome/chrome-copper alloy/copper/gold, an arrangement of titanium/titanium tungsten/copper, or an arrangement of copper/nickel/gold, that are suitable for the formation of the UBM structures 127. Any suitable materials or layers of material that may be used for the UBM structures 127 are fully intended to be included within the scope of the present disclosure.

In the example of FIG. 12, the vias 119, 119A, 119B, 119C, and 119D on the left form a first column of stacked vias that connects the conductive pad 53 with a respective connector 129, similar to those in FIG. 11. In addition, a second column of stacked vias, which has one less layer of via than the first column, connects a conductive feature (which may be a conductive line not visible in the cross-section of FIG. 12) with a respective connector 129.

Notably, a third column of stacked vias includes vias 119A1, 119B1, 119C1 and 119D1, where vias 119D1 and 119C1 are surrounded by dielectric structures 105, whereas vias 119B1 and 119A1 are not surrounded by dielectric structures 105 and are in direct contact with the dielectric layers 109. The third column of stacked via still offers advantage (e.g., improved protection against the cracks forming) over the reference design, which has no dielectric structures 105 formed at all.

FIG. 12 further illustrates a fourth column of stacked vias that include vias 119, 119A2, 119B2, 119C2, and 119D2. Some of the vias, such as vias 119D2 and 119C2, are surrounded by respective dielectric structures 105. The vias 119A2 and 119B2 are not surrounded by the dielectric structures 105, and are in direct contact with the dielectric layers 109. In addition, the vias 119A2 and 119B2 are staggered such that their center axes are not aligned along a same line, and instead, are spaced apart from each other (e.g., having lateral offsets in between). Conductive lines 110 may extend horizontally to connect the staggered vias. As discussed above, the staggered via design also alleviates the cracking issue. The staggered via design may be used here to provide flexibility in the routing of the conductive lines in the redistribution structure.

FIGS. 13A and 13B illustrate various views (e.g., cross-sectional view, perspective view) of a semiconductor package 100B, in accordance with yet another embodiment. The semiconductor package 100B is similar to the semiconductor package 100A, but the cross-section of the dielectric structures 105 have a trapezoidal shape instead of a rectangular shape. This may be caused by the exposure process (see, e.g., FIG. 3), which generates slanted sidewalls for the dielectric structure 105. Besides the rectangular shape and the trapezoidal shape, other shapes for the sidewalls of the dielectric structures 105 are also possible, and are fully intended to be included within the scope of the present disclosure.

FIG. 13B illustrates a perspective review of a portion of the semiconductor package 100B in a region indicated by the dashed box 120 in FIG. 13A. The portion in the dashed box 120 includes a portion (e.g., the lower portion 119L) of the via 119, a portion of the dielectric structure 105 around the via, and a portion of the dielectric layer 109 around the dielectric structure 105. As illustrated in FIG. 13B, the lower portion 119L of the via 119 has a diameter DV at the upper surface of the dielectric layer 109. The dielectric structure 105 has a diameter DDT at the upper surface of the dielectric layer 109, and has a diameter DDB proximate to the lower surface of the dielectric layer 109. In the illustrated embodiment, the diameter DDT is larger than the diameter DDB and the diameter DV. A ratio between the diameter DDT and the diameter DV may be 2.5 or larger, as an example.

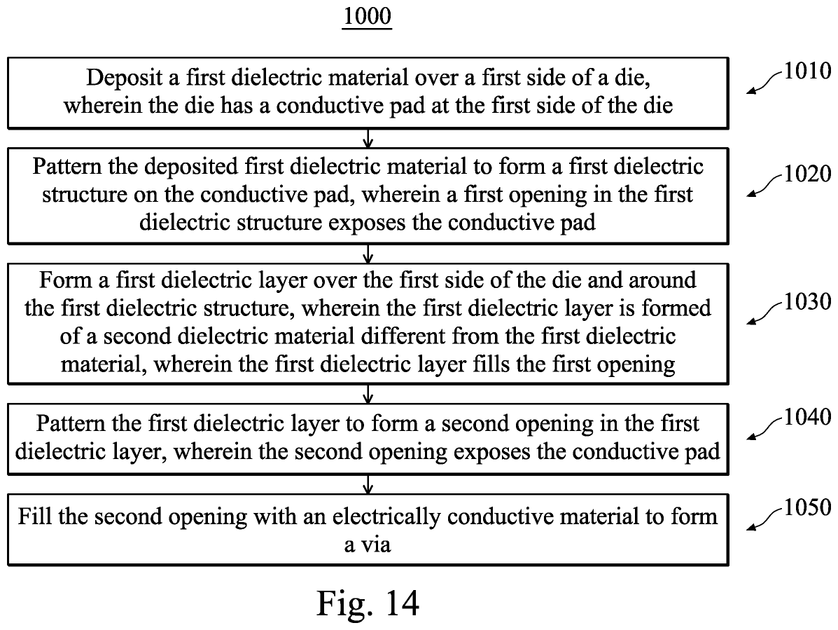

FIG. 14 illustrates a flow chart of a method of forming a semiconductor package, in accordance with an embodiment. At block 1010, a first dielectric material is deposited over a first side of a die, wherein the die has a conductive pad at the first side of the die. At block 1020, the deposited first dielectric material is patterned to form a first dielectric structure on the conductive pad, wherein a first opening in the first dielectric structure exposes the conductive pad. At block 1030, a first dielectric layer is formed over the first side of the die and around the first dielectric structure, wherein the first dielectric layer is formed of a second dielectric material different from the first dielectric material, wherein the first dielectric layer fills the first opening. At block 1040, the first dielectric layer is patterned to form a second opening in the first dielectric layer, wherein the second opening exposes the conductive pad. At block 1050, the second opening is filled with an electrically conductive material to form a via.

Variations and modifications to the disclosed embodiments are possible, and are fully intended to be included within the scope of the present disclosure. For example, in the illustrated embodiment, the dielectric structures 105 and the dielectric layers 109 are formed of photosensitive polymers which are patterned by performing an exposure process followed by a developing process. In alternative embodiments, the dielectric structures 105 and the dielectric layers 109 are formed of different dielectric materials that are not photosensitive polymers, in which case the patterning of the dielectric materials 105′ and 109 may be performed by a respective anisotropic etching process (e.g., anisotropic plasma etching) using a respective patterned mask layer as the etching mask. As another example, while the disclosed embodiments are used in forming vias in the redistribution structure of a semiconductor package, the disclosed methods/structure may also be used in forming vias (e.g., a single-layer of vias or vertically stacked vias) in other structures, such as vias in the interconnect structure of the semiconductor dies, through-silicon vias of semiconductor dies, or vias in printed-circuit board (PCB), and so on.

Disclosed embodiments achieve various advantage. For example, the vertically stacked via design reduced the electrical resistance, power consumption, and RC delay of the device formed. In addition, the vertically stacked via design allows for high-density integration due to its small footprint. The vertically stacked via design may be used for some, or all of, the layers of the redistribution structure, and may be used in conjunction with staggered via design to allow for design flexibility while still providing relief to the cracking issue.

In an embodiment, a semiconductor package includes: a die having a conductive pad at a first side of the die; and a redistribution structure over the first side of the die and electrically coupled to the die, comprising: a first dielectric layer comprising a first dielectric material; a first via in the first dielectric layer, wherein the first via is electrically coupled to the conductive pad of the die; and a first dielectric structure embedded in the first dielectric layer, wherein the first dielectric structure comprises a second dielectric material different from the first dielectric material, wherein the first dielectric structure laterally surrounds the first via and contacts sidewalls of the first via. In an embodiment, a second Young's modulus of the second dielectric material is higher than a first Young's modulus of the first dielectric material. In an embodiment, a second glass transition temperature of the second dielectric material is higher than a first glass transition temperature of the first dielectric material. In an embodiment, the first dielectric material is a first photosensitive polymer material, and the second dielectric material is a second photosensitive polymer material. In an embodiment, a first coefficient of thermal expansion (CTE) of the first dielectric material is substantially the same as a second CTE of the second dielectric material. In an embodiment, an upper surface of the first dielectric layer distal from the die is level with an upper surface of the first dielectric structure distal from the die, wherein a lower surface of the first dielectric layer facing the die is level with a lower surface of the first dielectric structure facing the die. In an embodiment, wherein the redistribution structure further comprises: a second dielectric layer comprising the first dielectric material, wherein the first dielectric layer is between the second dielectric layer and the die; a second via in the second dielectric layer, wherein the second via is electrically coupled to the first via, wherein a first center axis of the first via is aligned with a second center axis of the second via along a same line; and a second dielectric structure embedded in the second dielectric layer, wherein the second dielectric structure comprises the second dielectric material, wherein the second dielectric structure surrounds the second via and contacts sidewalls of the second via. In an embodiment, the redistribution structure further comprises: a third dielectric layer comprising the first dielectric material, wherein the third dielectric layer is between the first dielectric layer and the die; and a third via in the third dielectric layer, wherein the third via is electrically coupled to the first via, wherein the third dielectric layer surrounds and contacts sidewalls of the third via. In an embodiment, a third center axis of the third via is spaced apart from the first center axis of the first via, wherein the redistribution structure further comprises a conductive line connecting the first via and the third via. In an embodiment, a third center axis of the third via is aligned with the first center axis of the first via along the same line.

In an embodiment, a semiconductor package includes: a die having a conductive pad at a first side of the die; and a redistribution structure over the first side of the die and electrically coupled to the die, comprising: a first dielectric layer comprising a first dielectric material; a second dielectric layer comprising the first dielectric material, wherein the first dielectric layer is between the second dielectric layer and the die; a first via in the first dielectric layer and electrically coupled to the conductive pad of the die; a second via in the second dielectric layer and electrically coupled to the first via, wherein a first center axis of the first via and a second center axis of the second via are aligned along a same line; a first dielectric structure embedded in the first dielectric layer and around the first via, wherein the first dielectric structure comprises a second dielectric material different from the first dielectric material, wherein the first dielectric structure contacts sidewalls of the first via; and a second dielectric structure embedded in the second dielectric layer and around the second via, wherein the second dielectric structure comprises the second dielectric material and contacts sidewalls of the second via. In an embodiment, the second dielectric material has a higher Young's modulus than the first dielectric material, wherein the second dielectric material has a higher glass transition temperature than the first dielectric material. In an embodiment, a second coefficient of thermal expansion (CTE) of the second dielectric material is substantially the same as a first CTE of the first dielectric material. In an embodiment, the redistribution structure further comprises: a third dielectric layer comprising the first dielectric material, wherein the third dielectric layer is between the first dielectric layer and the die; and a third via in the third dielectric layer and electrically coupled to the first via, wherein the third dielectric layer contacts sidewalls of the third via. In an embodiment, a third center axis of the third via is spaced apart from the first center axis of the first via.

In an embodiment, a method of forming a semiconductor package includes: depositing a first dielectric material over a first side of a die, wherein the die has a conductive pad at the first side of the die; patterning the deposited first dielectric material to form a first dielectric structure on the conductive pad, wherein a first opening in the first dielectric structure exposes the conductive pad; forming a first dielectric layer over the first side of the die and around the first dielectric structure, wherein the first dielectric layer is formed of a second dielectric material different from the first dielectric material, wherein the first dielectric layer fills the first opening; patterning the first dielectric layer to form a second opening in the first dielectric layer, wherein the second opening exposes the conductive pad; and filling the second opening with an electrically conductive material to form a via. In an embodiment, the first dielectric material has a higher Young's modus than the second dielectric material, wherein the first dielectric material has a higher glass transition temperature than the second dielectric material. In an embodiment, the second dielectric material has a coefficient of thermal expansion (CTE) substantially the same as that of the first dielectric material. In an embodiment, the first dielectric material and the second dielectric material are different photosensitive polymer materials. In an embodiment, patterning the deposited first dielectric material comprises removing a first portion of the first dielectric material disposed directly over the conductive pad, removing a second portion of the first dielectric material disposed laterally distal from the conductive pad, and keeping a third portion of the first dielectric material contacting the conductive pad, wherein the third portion is between the first portion and the second portion, and partially overlaps with the conductive pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprises:
a die having a conductive pad at a first side of the die; and
a redistribution structure over the first side of the die and electrically coupled to the die, comprising:
a first dielectric layer comprising a first dielectric material;
a first via in the first dielectric layer, wherein the first via is electrically coupled to the conductive pad of the die; and
a first dielectric structure embedded in the first dielectric layer, wherein the first dielectric structure comprises a second dielectric material different from the first dielectric material, wherein the first dielectric structure laterally surrounds the first via and contacts sidewalls of the first via.

2. The semiconductor package of claim 1, wherein a second Young's modulus of the second dielectric material is higher than a first Young's modulus of the first dielectric material.

3. The semiconductor package of claim 2, wherein a second glass transition temperature of the second dielectric material is higher than a first glass transition temperature of the first dielectric material.

4. The semiconductor package of claim 3, wherein the first dielectric material is a first photosensitive polymer material, and the second dielectric material is a second photosensitive polymer material.

5. The semiconductor package of claim 3, wherein a first coefficient of thermal expansion (CTE) of the first dielectric material is substantially the same as a second CTE of the second dielectric material.

6. The semiconductor package of claim 5, wherein an upper surface of the first dielectric layer distal from the die is level with an upper surface of the first dielectric structure distal from the die, wherein a lower surface of the first dielectric layer facing the die is level with a lower surface of the first dielectric structure facing the die.

7. The semiconductor package of claim 3, wherein the redistribution structure further comprising:
a second dielectric layer comprising the first dielectric material, wherein the first dielectric layer is between the second dielectric layer and the die;
a second via in the second dielectric layer, wherein the second via is electrically coupled to the first via, wherein a first center axis of the first via is aligned with a second center axis of the second via along a same line; and
a second dielectric structure embedded in the second dielectric layer, wherein the second dielectric structure comprises the second dielectric material, wherein the second dielectric structure surrounds the second via and contacts sidewalls of the second via.

8. The semiconductor package of claim 7, wherein the redistribution structure further comprising:
a third dielectric layer comprising the first dielectric material, wherein the third dielectric layer is between the first dielectric layer and the die; and
a third via in the third dielectric layer, wherein the third via is electrically coupled to the first via, wherein the third dielectric layer surrounds and contacts sidewalls of the third via.

9. The semiconductor package of claim 8, wherein a third center axis of the third via is spaced apart from the first center axis of the first via, wherein the redistribution structure further comprises a conductive line connecting the first via and the third via.

10. The semiconductor package of claim 8, wherein a third center axis of the third via is aligned with the first center axis of the first via along the same line.

11. A semiconductor package comprises:
a die having a conductive pad at a first side of the die; and
a redistribution structure over the first side of the die and electrically coupled to the die, comprising:
a first dielectric layer comprising a first dielectric material;
a second dielectric layer comprising the first dielectric material, wherein the first dielectric layer is between the second dielectric layer and the die;
a first via in the first dielectric layer and electrically coupled to the conductive pad of the die;
a second via in the second dielectric layer and electrically coupled to the first via, wherein a first center axis of the first via and a second center axis of the second via are aligned along a same line;
a first dielectric structure embedded in the first dielectric layer and around the first via, wherein the first dielectric structure comprises a second dielectric material different from the first dielectric material, wherein the first dielectric structure contacts sidewalls of the first via; and
a second dielectric structure embedded in the second dielectric layer and around the second via, wherein the second dielectric structure comprises the second dielectric material and contacts sidewalls of the second via.

12. The semiconductor package of claim 11, wherein the second dielectric material has a higher Young's modulus than the first dielectric material, wherein the second dielectric material has a higher glass transition temperature than the first dielectric material.

13. The semiconductor package of claim 12, wherein a second coefficient of thermal expansion (CTE) of the second dielectric material is substantially the same as a first CTE of the first dielectric material.

14. The semiconductor package of claim 12, wherein the redistribution structure further comprises:
a third dielectric layer comprising the first dielectric material, wherein the third dielectric layer is between the first dielectric layer and the die; and
a third via in the third dielectric layer and electrically coupled to the first via, wherein the third dielectric layer contacts sidewalls of the third via.

15. The semiconductor package of claim 14, wherein a third center axis of the third via is spaced apart from the first center axis of the first via.

16. A method of forming a semiconductor package, the method comprising:
depositing a first dielectric material over a first side of a die, wherein the die has a conductive pad at the first side of the die;
patterning the deposited first dielectric material to form a first dielectric structure on the conductive pad, wherein a first opening in the first dielectric structure exposes the conductive pad;
forming a first dielectric layer over the first side of the die and around the first dielectric structure, wherein the first dielectric layer is formed of a second dielectric material different from the first dielectric material, wherein the first dielectric layer fills the first opening;
patterning the first dielectric layer to form a second opening in the first dielectric layer, wherein the second opening exposes the conductive pad; and
filling the second opening with an electrically conductive material to form a via.

17. The method of claim 16, wherein the first dielectric material has a higher Young's modus than the second dielectric material, wherein the first dielectric material has a higher glass transition temperature than the second dielectric material.

18. The method of claim 17, wherein the second dielectric material has a coefficient of thermal expansion (CTE) substantially the same as that of the first dielectric material.

19. The method of claim 17, wherein the first dielectric material and the second dielectric material are different photosensitive polymer materials.

20. The method of claim 17, wherein patterning the deposited first dielectric material comprises removing a first portion of the first dielectric material disposed directly over the conductive pad, removing a second portion of the first dielectric material disposed laterally distal from the conductive pad, and keeping a third portion of the first dielectric material contacting the conductive pad, wherein the third portion is between the first portion and the second portion, and partially overlaps with the conductive pad.
